(19) United States
(12) Patent Application Publication
(10) Pub. No.: US 2017/0331469 A1
(43) Pub. Date: Nov. 16, 2017

(54) METHOD AND DEVICE FOR OPERATING POWER SEMICONDUCTOR SWITCHES CONNECTED IN PARALLEL

(71) Applicant: Robert Bosch GmbH, Stuttgart (DE)

(72) Inventors: Jochen KILB, Sersheim (DE); Stefan ALDINGER, Bad Wimpfen (DE); Tobias RICHTER, Bietigheim-Bissingen (DE)

(21) Appl. No.: 15/529,795

(22) PCT Filed: Sep. 22, 2015
(86) PCT No.: PCT/EP2015/071696

§ 371 Date: May 25, 2017

(30) Foreign Application Priority Data
Nov. 26, 2014 (DE) 10 2014 224 168.5

(51) Int. Cl. H03K 17/0812; H02M 7/537; H03K 17/12; H02M 7/493; H03K 17/08

(52) U.S. Cl. CPC H03K 17/0812; H03K 17/12; H02M 7/493; H02M 7/537; H03K 2017/0806

(57) ABSTRACT

The invention relates to a method (100) and a control device (SG) for operating power semiconductor switches (LH1 . . . LHn) connected in parallel, having the following steps: determining a nominal value for a total gate series resistor (GGVL . . . GGVn) of at least one power semiconductor switch (LH1 . . . LHn); providing the total gate series resistor (GGV1 . . . GGVn) for the at least one power semiconductor switch (LH1 . . . LHn) depending on the relevant nominal value, and operating the at least one power semiconductor switch (LH1 . . . LHn) with the associated total gate series resistor (GGV1 . . . GGVn).

### BACKGROUND OF THE INVENTION

The invention relates to a method and a control device for operating power semiconductor switches connected in parallel. Furthermore, the invention relates to an electrical circuit, an electrical system comprising the control device, a computer program for carrying out said method, and a machine-readable storage medium.

Inverters are usually used for operating electrical drives, said inverters converting the electrical energy from a DC voltage source, e.g. a battery, into an AC voltage, in order to supply an electrical machine, e.g. an asynchronous machine, with AC voltage or AC current. The inverter has so-called half-bridges for this purpose. Said half-bridges have power semiconductor switches, by means of which the DC current and the DC voltage are switched in a clocked fashion, such that an AC voltage and an AC current arise at the output terminals of the inverter. Upper limits of current are predefined for said power semiconductor switches, the power semiconductor switches being damaged irreversibly in the event of said upper limits being exceeded. If higher currents are required, then, for the operation of the electrical drive, said power semiconductor switches in the inverters are connected in parallel. On account of component tolerances, however, the power semiconductor switches are loaded to different extents even during parallel operation, since the semiconductors do not switch on simultaneously and, therefore, one of the semiconductors possibly switches on earlier than another. This can have the effect that the current flow between the switches is divided unequally and individual power semiconductor switches are thus thermally loaded to a greater extent and thus fail more rapidly. A circuit construction that minimizes the propagation time differences between the control signals, which differences should likewise be taken into account, in the control of power semiconductor switches connected in parallel, is known from WO 2011/120728 A2.

There is therefore the need to develop alternatives thereto which enable a uniform loading of the power semiconductor switches connected in parallel. This will prevent individual power semiconductor switches from being overloaded and failing prematurely. Consequently, the robustness of the overall device will increase as well.

### SUMMARY OF THE INVENTION

A method for operating power semiconductor switches connected in parallel is provided, wherein a total gate series resistor is assigned to at least one of the power semiconductor switches, said method comprising the following steps:

ascertaining a setpoint value for the total gate series resistor of the at least one power semiconductor switch, forming the total gate series resistor for the at least one power semiconductor switch depending on the setpoint value, and operating the at least one power semiconductor switch with the associated total gate series resistor.

Power semiconductor switches connected in parallel are a plurality, that is to say a multiplicity, of power semiconductor switches which are opened or closed, that is to say controlled, depending on a common signal. A current flow through a power semiconductor switch is prevented as long as the power semiconductor switch is open. A current flow through a power semiconductor switch is enabled as long as the power semiconductor switch is closed. In order to close a power semiconductor switch, a voltage is applied to the gate terminal by means of a voltage source. A gate series resistor is usually connected between the voltage source and the gate terminal. On account of the electrodynamic processes in such an electrical circuit, depending on the value of said gate series resistor, a power semiconductor switch switches over from opening to closing, or vice versa, somewhat earlier or later after the connection or disconnection of the voltage source. A faster switchover takes place in the case of smaller gate series resistors; the switchover is delayed in the case of larger gate series resistors. Consequently, the switching time can be varied by increasing or decreasing the value of a gate series resistor. Accordingly, the method according to the invention comprises a step for ascertaining a setpoint value for a total gate series resistor for at least one of the power semiconductor switches connected in parallel. According to the invention, the total gate series resistor is variably adjustable. Therefore, a setpoint value for the total gate series resistor of the power semiconductor switch is ascertained depending on present operating conditions of the power semiconductor switch connected in parallel. As a further step, provision is made for forming said total gate series resistor for the at least one power semiconductor switch depending on the respective setpoint value. The variable total gate series resistor thus acquires a resistance value corresponding to the setpoint value. After the total gate series resistor has been formed in a manner corresponding to its setpoint value, the corresponding power semiconductor switch is operated by means of the associated total gate series resistor.

Advantageously, therefore, by ascertaining or by predefining a setpoint value for the at least one total gate series resistor and forming the total gate series resistor, a method for operating power semiconductor switches connected in parallel is provided which makes it possible to operate the individual power semiconductor switches in a manner corresponding to their present operating state. In this regard, individual operation of the individual power semiconductor switches connected in parallel depending on their present properties is possible. This affords the possibility of individually loading the individual power semiconductor switches and, in particular, uniformly loading the power semiconductor switches. This advantageously affords the possibility of using components with greater tolerance or variation. It is even possible to dispense with a prior tolerance determination or classification of the components before use. Furthermore, this results in an increase in the component yield and the test process on the part of the manufacturer can be simplified. Not least, the costs are thus reduced. Furthermore, there is the possibility of connecting in parallel power semiconductor switches of different power classes or chip areas, wherein an overloading of a weaker component is avoided on account of the individual loading. The scalability of the power area of the overall device is also simplified since power semiconductor switch modules comprising different power semiconductor switches can be used together.

In one configuration of the invention, the method comprises the following additional steps: providing a multiplicity of gate series resistors which can be assigned to the at least one total gate series resistor, and selecting a selection from the multiplicity of gate series resistors depending on the setpoint value ascertained, wherein forming the at least one total gate series resistor is carried out by interconnecting the selected gate series resistors.

There are certainly various possibilities for realizing the variable total gate series resistors. One of them, for example, is to keep available a multiplicity of gate series resistors. Said gate series resistors can be assigned to the total gate series resistor of the at least one power semiconductor switch of the power semiconductor switches connected in parallel. This means that, instead of a constant total gate series resistor, a multiplicity of, in particular constant or invariable, gate series resistors are provided which can be assigned at least partly to a total gate series resistor. A selection or a number from the multiplicity of gate series resistors is then selected depending on the ascertained setpoint value for a total gate series resistor. The total gate series resistor for the at least one power semiconductor switch is formed by subsequent electrical interconnection, in particular connection at least partly in series and/or in parallel, of the individual gate series resistors from the selection. In particular, selections of gate series resistors having for example resistance values corresponding to the binary number sequence (1, 2, 4, 8, 16, . . . ) are suitable for this purpose. It is thus possible to realize a total gate series resistor having any desired resistance value corresponding to the ascertained setpoint value by electrical interconnection, in particular by means of series connection.

Advantageously, this method affords a possibility of providing variable total gate series resistors for the parallel control of power semiconductor switches.

In another configuration of the invention, the method comprises the following additional step: ascertaining at least one respective temperature of at least one first and one second one of the power semiconductor switches, wherein ascertaining the setpoint value is carried out depending on the temperatures ascertained.

The greater the extent to which a power semiconductor switch is loaded, that is to say the higher the current that flows through the power semiconductor switch, the greater the extent to which the power semiconductor switch heats up. Consequently, in the case of power semiconductor switches connected and operated in parallel, the one that is hotter is loaded to a greater extent. By ascertaining and comparing the temperature of two power semiconductor switches, it is thus possible to establish which of the two power semiconductor switches is loaded to the greater extent. Ascertaining the temperature of a power semiconductor switch is carried out for example by means of a temperature sensor fitted within the power semiconductor switch module. However, there are also other possibilities for determining the temperature of a power semiconductor switch, e.g. by means of a very accurate current measurement through the power semiconductor switch, since the heating of the power semiconductor switch correlates with the current. By varying the total gate series resistor, during further operation of the power semiconductor switch, the hotter power semiconductor switch, that is to say the one previously loaded to a greater extent or above average, will be loaded to a lesser extent and the power semiconductor switch loaded more weakly will be loaded to a greater extent. The loading of the power semiconductor switches to different extents is influenced by varying or by adjusting the total gate series resistor. For this purpose, the setpoint value for the total gate series resistor is determined and ascertained depending on the measured temperatures.

Advantageously, a method is provided here for ascertaining the setpoint value for the at least one total gate series resistor.

In another configuration of the invention, the setpoint value for the total gate series resistor is ascertained depending on a difference between the ascertained temperatures of the at least first and second power semiconductor switches.

This means that the difference in temperature between two power semiconductor switches is a measure of the extent to which the loading of the two power semiconductor switches deviates from one to the other. The setpoint value for the total gate series resistor or in particular the difference between the setpoint values for the total series resistor of the corresponding power semiconductor switches is thus defined depending on the ascertained temperature difference between at least two of the power semiconductor switches.

Advantageously, a method is thus provided which makes it possible to ascertain the setpoint value for a total gate series resistor for the at least one power semiconductor switch or for the total gate series resistors of the first and second power semiconductor switches.

In another configuration of the invention, the method comprises a further additional step: ascertaining a respective current through at least one first and one second one of the power semiconductor switches, wherein ascertaining the at least one setpoint value is carried out depending on the currents ascertained.

This means that the currents of at least two of the power semiconductor switches are measured. By way of example, this is possible by means of a sense output at the individual power semiconductor switches, other methods for measuring the current through a power semiconductor switch also being conceivable. Once again the setpoint value of the total gate series resistor is implemented depending on the currents ascertained. That power semiconductor switch through which the higher electric current flows is loaded to a greater extent. In order to realize a uniform or balanced loading of the power semiconductor switches, the setpoint value for the total gate series resistor is ascertained depending on the currents ascertained.

Advantageously, a further method is provided for ascertaining the setpoint value for the at least one total gate series resistor.

In another configuration of the invention, the setpoint value for the total gate series resistor is ascertained depending on a difference between the ascertained currents through the at least first and second power semiconductor switches.

This means that by means of subtraction, for example, the difference between the two currents flowing through the power semiconductor switches is ascertained, and the setpoint value for the total gate series resistor is defined depending on the difference. The greater the current difference, the greater too the extent to which the setpoint values for the respective total gate series resistors deviate from one another.

Advantageously, a further method is provided for ascertaining the setpoint value for the at least one total gate series resistor.

In another configuration of the invention, ascertaining the setpoint value, forming the total gate series resistor and operating at least one of the power semiconductor switches are carried out by means of at least one logic unit.

This means that provision is made of a logic unit, for example a microprocessor, for ascertaining the setpoint value, for forming the total gate series resistor and operating the at least one of the power semiconductor switches. Operating a power semiconductor switch should be understood here to mean, in particular, that a voltage is connected or disconnected in order to influence the current conductivity of the power semiconductor switch.

Advantageously, a method is thus provided which can control and process the steps of the method.

In another configuration of the invention, at least partly parallel-connected power semiconductor modules are used as power semiconductor switches connected in parallel, wherein a power semiconductor module comprises power semiconductor switches connected in parallel.

That means that at least partly parallel-connected power semiconductor modules are used instead of individual, individually controllable power semiconductor switches connected in parallel. In this case, a power semiconductor module corresponds to a parallel circuit comprising a plurality of power semiconductor switches whose input, output and control terminals are respectively combined. Such power semiconductor modules are known in various sizes and power classes and are used for current carrying and interruption of higher electrical powers by means of a control signal.

Advantageously, operation of parallel-connected power semiconductor modules is thus made possible in which the individual power semiconductor modules are likewise loaded more uniformly than when all the power semiconductor modules are controlled by means of a control signal and, on account of their component tolerances or their different dimensioning, react to a control signal at different speeds and with different sensitivities. Consequently, advantages comparable to those afforded for the operation of power semiconductor switches connected in parallel are afforded for the operation of the power semiconductor modules connected in parallel.

Furthermore, a control device for operating power semiconductor switches connected in parallel is provided, wherein a total gate series resistor is assigned to at least one of the power semiconductor switches and the control device is designed to ascertain a setpoint value for the total gate series resistor of the at least one power semiconductor switch, to form the total gate series resistor of the at least one power semiconductor switch depending on the respective setpoint value, and to operate the at least one power semiconductor switch with the associated total gate series resistor.

According to the invention, the total gate series resistors are variably adjustable by means of the control device. Therefore, a setpoint value for a total gate series resistor for the at least one power semiconductor switch is ascertained depending on present operating conditions of the power semiconductor switches connected in parallel. As a further step, provision is made for forming said total gate series resistor of the power semiconductor switch depending on the setpoint value. The variable total gate series resistor thus acquires a resistance value corresponding to the setpoint value. After the total gate series resistor has been formed in a manner corresponding to its setpoint value, the corresponding power semiconductor switch is operated by means of the associated total gate series resistor.

Advantageously, therefore, by ascertaining or by predefining a setpoint value for a total gate series resistor and forming the total gate series resistor, a control device for operating power semiconductor switches connected in parallel is provided which makes it possible to operate the power semiconductor switches in a manner corresponding to their present operating state. The possibility is afforded of individually operating and loading the power semiconductors, and thus also uniformly loading the power semiconductor switches, in particular depending on their present properties. This therefore advantageously affords the possibility of using components with greater tolerance or variation, or it is even possible to dispense with a prior tolerance determination or classification of the components before use.

Furthermore, an electrical circuit, in particular an inverter or a pulse-controlled inverter, is provided. It comprises power semiconductor switches connected in parallel, wherein a total gate series resistor is assigned to at least one of the power semiconductor switches. The value of the total gate series resistor is variably adjustable.

Advantageously, a circuit is provided which enables an individual control of the at least one of the power semiconductor switches connected in parallel. By means of a variably adjustable total gate series resistor, by varying the resistance value it is possible to accelerate or slow down the switching behavior of the at least one power semiconductor switch in comparison with the power semiconductor switches connected in parallel.

Furthermore, an electrical system comprising power semiconductor switches connected in parallel is provided, comprising total gate series resistors and a control device for operating the power semiconductor switches connected in parallel.

Advantageously, an electrical system comprising power semiconductor switches connected in parallel is thus provided. Variable total gate series resistors are provided which make it possible to operate the power semiconductor switches connected in parallel and in the process to load the power semiconductor switches uniformly or in a balanced fashion.

Furthermore, a computer program is provided which is designed to perform all the steps of one of the methods described above.

Furthermore, a machine-readable storage medium is provided on which the computer program described is stored.

It goes without saying that the features, properties and advantages of the method according to the invention correspondingly apply or are applicable to the control device according to the invention and/or to the electrical system, and vice versa.

### BRIEF DESCRIPTION OF THE DRAWINGS

Further features and advantages of embodiments of the invention are evident from the following description with reference to the accompanying drawings.

The invention will be explained in greater detail below with reference to some figures. To that end, in the figures:

FIG. 1 shows an electrical system comprising a control device in a schematic illustration

FIG. 2 shows an excerpt from the electrical system from FIG. 1

FIG. 3 shows a flow diagram for a method for operating power semiconductor switches connected in parallel.

### DETAILED DESCRIPTION

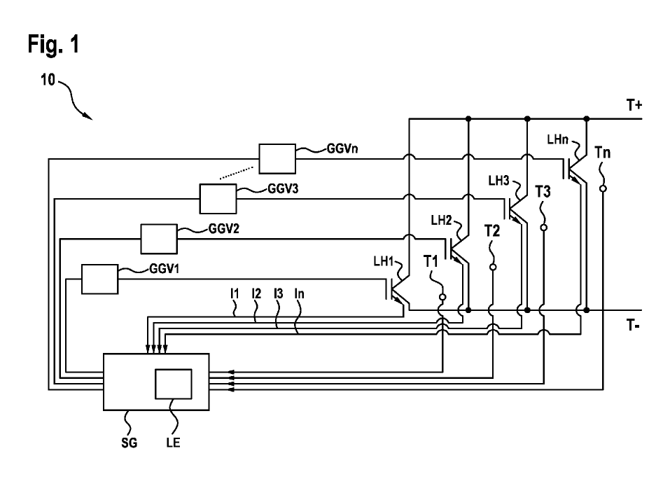

FIG. 1 shows an electrical system 10 in a schematic illustration. The electrical system 10 comprises power semiconductor switches LH1, LH2, LH3 . . . LHn, which are connected in parallel and conduct an electric current from the potential T+to the potential T− in the closed state and isolate the potentials in the open state. The gate terminals of the power semiconductor switches LH1 . . . LHn are connected to the respective total gate series resistors GGV1, GGV2, GGV3 . . . GGVn. Furthermore, a control device SG is provided, which is connected via the individual total gate series resistors GGV1 . . . GGVn to the individual gate terminals of the power semiconductor switches LH1 . . . LHn. By applying a voltage by means of voltage source (not illustrated) at the gate terminals of the power semiconductor switches LH1 . . . LHn, the power switches are controlled or a current flow through them is made possible; by removing or disconnecting the voltage at the gate terminals of the power semiconductor switches LH1 . . . LHn, the current flow through the latter is interrupted. Furthermore, temperature sensors T1, T2, T3 . . . Tn are provided for ascertaining the temperatures at the individual power semiconductor switches. The temperature sensors can be fitted directly on the individual semiconductors. A different position of the temperature sensors is also conceivable if the temperature value ascertained can be assigned to a corresponding power semiconductor switch LH1 . . . LHn and the temperature of the corresponding power semiconductor switch LH1 . . . LHn can be deduced therefrom. Furthermore, the power semiconductor switches LH1 . . . LHn have the sense terminals. By means of the latter, the control device can determine the current intensity through the individual power semiconductor switches LH1 . . . LHn. Here, too, other variants for measuring the current through the individual power semiconductor switches LH1 . . . LHn are conceivable. It should once again be possible to assign an ascertained current value to a power semiconductor switch. Depending on the temperatures ascertained and/or the currents ascertained, the control device in each case ascertains setpoint values for the total gate series resistors GGV1 . . . GGVn by means of which the power semiconductor switches LH1 . . . LHn are operated. Particularly in the case of a combined ascertainment of the setpoint values depending on the ascertained temperatures and currents, it is possible to predefine the setpoint values for the total gate series resistors GGV1 . . . GGVn even more exactly. The control device SG furthermore comprises a logic unit LE, which performs and controls the process of ascertaining the setpoint value, the process of forming the total gate series resistor GGVn and the operation of the at least one of the power semiconductor switches LHn.

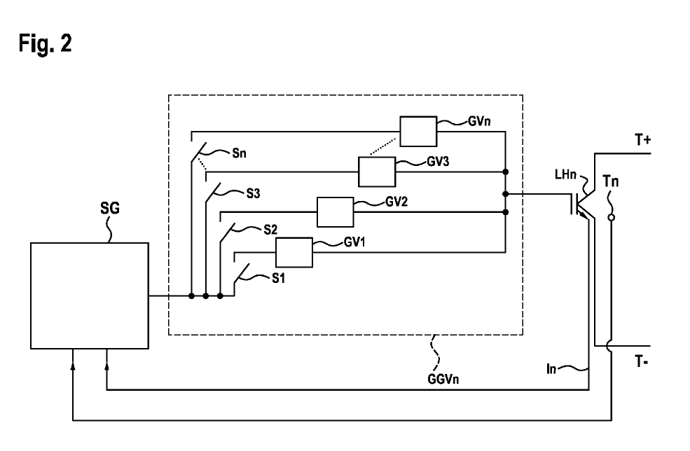

FIG. 2 shows the construction of a variably adjustable total gate series resistor GGVn in particular in a schematic form. A multiplicity of gate series resistors GVn, GV1, GV2, GV3 . . . GVn are assigned to the total gate series resistor GGVn. With the aid of the switches S1, S2, S3 . . . Sn, the gate series resistors GV1 . . . GVn can be interconnected or combined in any desired way, thus ultimately resulting in a total gate series resistor GGVn having a value corresponding to the setpoint value, that is to say a resistance value corresponding to the setpoint value. FIG. 2 only illustrates a parallel connection of the gate series resistors, but a series connection or a combination of series and parallel connection can also be used as necessary. By controlling the switches S1 . . . Sn, it is thus possible to configure total gate series resistors GGVn with any desired setpoint value. In this case, the control of the switches S1 . . . Sn can be carried out in particular by the control device. A corresponding connection from the control device to the switches S1 . . . Sn is not included in the drawing, for reasons of clarity, but is of course provided. Depending on the operating condition of the power switch LHn, that is to say in particular depending on the temperature Tn and/or the current In, the control device SG ascertains a setpoint value for the total gate series resistor GGVn. From the provided multiplicity of gate series resistors, by means of selection via the switches S1 . . . Sn, a total gate series resistor GGVn is configured in a manner corresponding to the setpoint value. Operation of the power semiconductor switch LHn by the control device SG is thus carried out via the correspondingly set total gate series resistor GGVn.

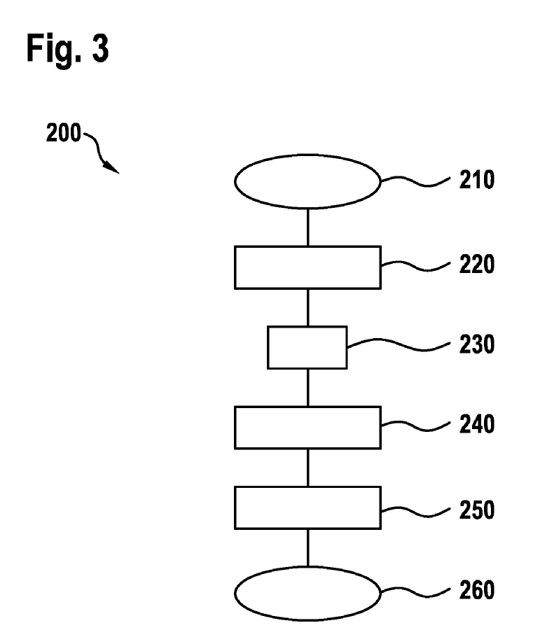

FIG. 3 shows a method 200 for operating power semiconductor switches connected in parallel. The method starts in step 210. A setpoint value for a total gate series resistor GGVn for the at least one power semiconductor switch LHn is ascertained in step 220. In step 230, optionally, a multiplicity of gate series resistors GVn which can be assigned to the total gate series resistor GGVn are provided and a selection of the gate series resistors GVn is selected depending on the setpoint value ascertained. In step 240, the total gate series resistor GGVn for the at least one power semiconductor switch LHn is formed depending on the respective setpoint value, in particular by interconnection of the selection of the gate series resistors GVn. In step 250, the at least one power semiconductor switch is operated with the associated total gate series resistor GGVn. The method ends in step 260.

1. A method for operating power semiconductor switches (LH1 . . . LHn) connected in parallel, wherein a total gate series resistor (GGV1 . . . GGVn) is assigned to at least one of the power semiconductor switches (LH1 . . . LHn), the method comprising:
ascertaining (220), via a control device, a setpoint value for the total gate series resistor (GGV1 . . . GGVn) of the at least one power semiconductor switch (LH1 . . . LHn),
forming (240), via the control device, the total gate series resistor (GGV1 . . . GGVn) for the at least one power semiconductor switch (LH1 . . . LHn) depending on the setpoint value, and
operating (250), via the control device, the at least one power semiconductor switch (LH1 . . . LHn) with the associated total gate series resistor (GGV1 . . . GGVn).

2. The method as claimed in claim 1 comprising the following additional steps:
providing (230) a multiplicity of gate series resistors (GV1 . . . GVn) which can be assigned to the at least one total gate series resistor (GGV1 . . . GGVn), and
selecting a selection from the multiplicity of gate series resistors (GV1 . . . GVn) depending on the setpoint value ascertained,
wherein forming (240) the at least one total gate series resistor (GGV1 . . . GGVn) is carried out by interconnecting the selected gate series resistors (GV1 . . . GVn).

3. The method as claimed in claim 1 comprising the following additional step:
ascertaining a respective temperature (T1 . . . Tn) of at least one first and one second one of the power semiconductor switches (LH1 . . . LHn),
wherein ascertaining the at least one setpoint value is carried out depending on the temperatures (T1 . . .Tn) ascertained.

4. The method as claimed in claim 3, wherein ascertaining the at least one setpoint value is carried out depending on a difference between the ascertained temperatures (T1 . . . Tn) of the at least first and second power semiconductor switches (LH1 . . . LHn).

5. The method as claimed in claim 1 comprising the following additional step:
ascertaining a respective current (I1 . . . In) through at least one first and one second one of the power semiconductor switches (LH1 . . . LHn), wherein ascertaining the at least one setpoint value is carried out depending on the currents (I1 . . . In) ascertained.

6. The method as claimed in claim 5, wherein ascertaining the at least one setpoint value is carried out depending on a difference between the ascertained currents (I1 . . . In) through the at least first and second power semiconductor switches (LH1 . . . LHn).

7. The method as claimed in claim 1, wherein ascertaining the setpoint value, forming the total gate series resistor (GGV1 . . . GGVn) and operating the at least one of the power semiconductor switches (LH1 . . . LHn) are carried out by means of at least one logic unit (LE).

8. The method as claimed in claim 1, wherein at least partly parallel-connected power semiconductor modules are used as power semiconductor switches (LH1 . . . LHn) connected in parallel, wherein a power semiconductor module comprises power semiconductor switches connected in parallel.

9. A control device (SG) for operating power semiconductor switches (LH1 . . . LHn) connected in parallel, wherein a total gate series resistor (GGV1 . . . GGVn) is assigned to at least one of the power semiconductor switches (LH1 . . . LHn) and the control device (SG), wherein the control device is configured
to ascertain a setpoint value for the total gate series resistor (GGV1 . . . GGVn) of the at least one power semiconductor switch (LH1 . . . LHn),
to form the total gate series resistor (GGV1 . . . GGVn) of the at least one power semiconductor switch (LH1 . . . LHn) depending on the setpoint value,
and to operate the at least one power semiconductor switch (LH1 . . . LHn) with the associated total gate series resistor (GGV1 . . . GGVn).

10. An electrical circuit comprising power semiconductor switches (LH1 . . . LHn) connected in parallel, wherein a total gate series resistor (GGV1 . . . GGVn) is assigned to at least one of the power semiconductor switches (LH1 . . . LHn), wherein the value of the total gate series resistor (GGV1 . . . GGVn) is variably adjustable.

11. An electrical system (10) comprising power semiconductor switches (LH1 . . . LHn) connected in parallel, comprising total gate series resistors (GGV1 . . . GGVn) and a control device (SG) configured
to ascertain a setpoint value for the total gate series resistor (GGV1 . . . GGVn) of the at least one power semiconductor switch (LH1 . . . LHn),
to form the total gate series resistor (GGV1 . . . GGVn) of the at least one power semiconductor switch (LH1 . . . LHn) depending on the setpoint value,
and to operate the at least one power semiconductor switch (LH1 . . . LHn) with the associated total gate series resistor (GGV1 . . . GGVn).

12. (canceled)

13. A non-transitory machine-readable storage that when executed on a computer, cause the computer to
ascertain a setpoint value for the total gate series resistor of at least one power semiconductor switch,
control forming the total gate series resistor for the at least one power semiconductor switch the setpoint value, and
operate the at least one power semiconductor switch with the associated total gate series resistor.
